(19) United States
(12) Patent Application Publication
(10) Pub. No.: US 2015/0309130 A1
(43) Pub. Date: Oct. 29, 2015

(54) Magnetic Resonance (MR) Field Cycling Instrument and Methods Associated Therewith

(71) Applicants: Constantin Job, Tucson, AZ (US); Della M. McDonough, Tucson, AZ (US)

(72) Inventors: Constantin Job, Tucson, AZ (US); Della M. McDonough, Tucson, AZ (US)

(21) Appl. No.: 14/670,612

(22) Filed: Mar. 27, 2015

Related U.S. Application Data
(60) Provisional application No. 61/970,983, filed on Mar. 27, 2014.

(51) Int. Cl. G01R 33/28

(52) U.S. Cl. CPC G01R 33/282

(57) ABSTRACT

A system and method for fast magnetic field-cycling of electrically powered solenoids and new method of stabilizing magnetic fields is disclosed.

This application claims priority under 35 USC 119(e) to U.S. Provisional Application No. 61/970,983 filed Mar. 27, 2014. the entire contents of which are incorporated by reference in its entirety.

The following invention was supported by NSF grant No. 1315800. Accordingly, the federal government has rights in this invention.

### FIELD OF THE INVENTION

The present invention relates to a novel field cycling magnetic resonance instrument that employs electronic fast switching insolated gated bipolar transistors and a storage capacitor. In one embodiment, the present invention relates to a field cycling instrument with magnetic field regulation that allows the use of magnetic field gradients XYZ.

### BACKGROUND OF THE INVENTION

Detecting cell receptors with MRI (magnetic resonance imaging) has been a “holy grail” in molecular imaging research for the last 15 years. However; MRI generally lacks the sensitivity to detect cell receptors at physiologically relevant levels. To overcome this drawback, dynamic nuclear polarization (DNP) has been used for a number of years to improve the inherent low sensitivity of magnetic resonance spectroscopic methods, and recently it has been combined with Magnetic Resonance Imaging (MRI) to produce an imaging modality known as Overhauser-Enhanced MRI (OMRI). However, conventional MRI has drawbacks including the inability to measure a wide range of magnetic field strengths because standard MRI scanners are fixed at a single magnetic field strength. Conventional MR also is unable to measure the variation of a sample's T1 relaxation time as a function of magnetic field. If one were able to produce T1 dispersion plots as a function of field strength, one could derive more accurate and/or quicker information on the behavior of samples or tissues at the molecular level. Thus, it is desired that a unique MRI field-cycling unit be procured that can potentially perform molecular imaging studies that cannot be performed with other imaging modalities (such as conventional MR).

Large magnets (for example, about 20 cm in an inner diameter) previously were not usable for MR field cycling experiments because the electronic switching time was not sufficiently rapid. In order to use this large magnet for MR field-cycling experiments an electronic switching time on the order of 10 msec or less have to be attained. Previously, this was unknown.

### SUMMARY OF THE INVENTION

The present invention relates to a modern, state-of-the-art magnetic resonance (MR) field-cycling instrument as well as its design and construction. Using the instrument of the present invention, MR images and MR spectra of both in-vitro and in-vivo experiments can be measured, and spin-lattice relaxation times (T1) can be investigated over a broad range of magnetic field strengths ranging from 0 to 0.5 T (Tesla). Moreover, the present invention relates to a large magnet size that can only be used for MR experiments by having a sufficiently fast electronic switching time. The instrument is based upon a magnet with a bore site of about 20 cm suitable for small animal imaging (although it should be recognized that other sizes can be used). In an embodiment, the present invention relates to magnetic field cycling that is accomplished electronically by utilizing fast switching insulated gated bipolar transistors (IGBT) and a storage capacitor. In one embodiment, the present invention relates to a unique design that includes a magnetic field regulation that allows the use of magnetic field gradients XYZ.

### BRIEF DESCRIPTION OF THE VARIOUS VIEWS OF THE DRAWINGS

FIG. 1 shows a block diagram of the field-cycling electronics according to the present invention,

FIG. 2 illustrates the field-cycling switching network with G1-G4 representing high power insulated gated bipolar transistor (IGBT): D1-D7 represent high voltage diodes; A represents a current amplifier, R1, R2 represent 0.57 ohm resistors having an equal value to the resistance of the magnet M. S1-S5 represent Shunts; and F represents a fuse.

FIGS. 3A-C illustrate the summary of principles of magnetic field-cycling sequence for measurement of Overhauser Enhanced MRI or MRS indicating the polarization, evolution (irradiation), and detection (MRI experiment) periods. FIG. 3A shows the main coil current, FIG. 313 shows the main coil voltage and FIG. 3C shows the voltage of the current amplifier.

FIG. 4 shows a block diagram of the shunt voltage detection and the IGBT switching

FIG. 5 illustrates how the Z-gradient waveform is utilized to drive the current amplifier enabling MRI console control over the magnetic field-cycling.

FIG. 6 shows a block diagram illustrating how magnetic field stability is achieved when using XYZ gradients.

### DETAILED DESCRIPTION OF THE INVENTION

The advantage of Fast Field-Cycling (FFC) MRI over conventional MRI is its ability to make measurements and collect images over a wide range of magnetic field strengths, whereas standard MRI scanners are fixed at a single value of magnetic field. FFC-MRI can measure the variation of a sample's T1 relaxation time as a function of magnetic field, using a method called relaxometry. The T1 dispersion plots produced provide information on the behavior of samples or tissues at the molecular level, and are sensitive to changes in the concentration and motion of proteins, making FFC a potential detector and monitor of disease.

In one embodiment, the application of magnetic field-cycling, methods in magnetic resonance imaging and spectroscopy represents a powerfill approach for investigating accurate, sensitive, and repeated measurements of the Oxygen concentration (pO₂) in tissues utilizing Overhauser Enhanced MRI (OMRI) and MRS with magnetic field-cycling. The ability to measure oxygen concentration is especially important for the optimization of cancer therapy. Its precision and accuracy will be compatible (at a lesser cost) with a standard MRI experiment. Several contrast agents have already been developed for generating oxygen images. The extent of hyperpolarization depends on the concentration of the agent and the EPR line width derivatives. This enables the generation of pure oxygen images and computation of absolute oxygen concentration (pO2) in tissues and of particular interest in tumors. The range of applications of OMRI encompasses many aspects of the molecular imaging field.

Magnetic field-cycling is a preferred technique for obtaining the frequency (or magnetic field) dependence of relaxation times at low fields where signal to noise in constant field strength MR is insufficient.

The temporal exposure of a sample to a lower magnetic field can be performed either by electronically switching the current in a magnet or by moving the sample mechanically, normally pneumatically, between positions of different magnetic flux densities. The latter technique takes more time to switch between different fields and is generally not practical for MRI field-cycling. Prior to the present invention, last electronic switching was not known for magnets with bore size of 20 cm or more.

Magnetic field-cycling has been limited to small samples due to the inability to ramp the field of larger inductance at an acceptable switching rate. Thus, in an embodiment, the present invention relates to a magnetic field cycling instrument that is able to accommodate large sample sizes. The electronics and the various components of the field cycling instrument are ideally suited for this larger sample size. In an embodiment, the bore of the magnet has as 20 cm inner diameter allowing one to accommodate sample sizes that have a diameter that is close to 10 cm. Alternatively, the sample size is 8 cm in diameter, In an alternate embodiment, the sample size is 5 cm in diameter. Alternatively, the sample size is 1 cm, 2 cm, 3 cm, or 4 cm in diameter.

In one embodiment, the length of the magnet is 80 cm in length allowing one to accommodate sample sizes that are close to 10 cm in length. In one embodiment, the sample size is about 8 cm in length. Alternatively, the sample size is 5 cm in length. In an alternate embodiment, the sample size is 3 cm in length. Alternatively, the sample size is 1 cm, or 2 cm, in length.

In one embodiment, the present invention relates to being able to apply field-cycling techniques to magnetic resonance imaging and take advantage of hyper-polarization (e.g. Overhauser Enhanced techniques). Typically, to take advantage of hyper-polarization larger magnets and magnet bores for pre-clinical and clinical MRI are required. Previously, the electronics that were available were insufficient to rapidly switch magnetic fields to attain larger inductance. Thus, in an embodiment of the present invention, the field cycling instruments of the present invention comprises new field-cycling electronics that are able to switch the magnetic field for the larger inductance. Moreover, in an embodiment, the present invention has electronics that allow for magnet field stabilization that enables MR imaging and MR spectroscopy.

Accordingly, in one embodiment of the present invention, as new approach to switching fields of larger magnets has been attained while simultaneously maintaining magnetic field stability good enough for MRI imaging. Thus, in an embodiment, the MRI field cycling instrument and associated methods of the present invention will allow molecular imaging studies to be performed that were previously unattainable.

The present invention will now be described in connection with the various figures. Although the description describes the precise system that was used to obtain the fast electronic switching that is provides the advantages enumerated above, it should be understood that modifications can be made to achieve the same results without departing from the spirit and scope of the present invention.

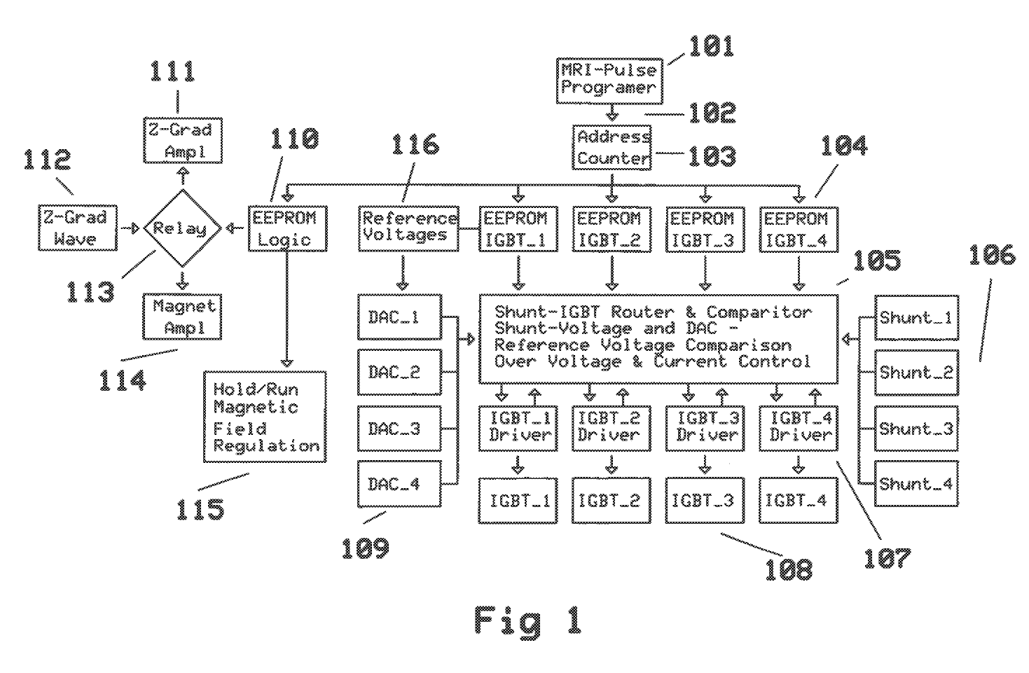

### Block Diagram (FIG. 1)

The interface from the field-cycling instrument to the MRI or NMR instrument 101 consists of 5 coax cables. Three coax cables 102 are optically isolated and clock the address counter 103 on the security and Driver logic (SDL) hoard to advance the addresses of the EEPROMS 104 according to the preprogrammed field-cycling MRI sequence. The three signals are RESET (Standby), ARM (get the field-cycling electronics ready) and ADVANCE (advances the address of the EEPROMS to generate the control signals for to particular preprogramed sequence).

Each of the four IGBTs (Insulated Gate Bipolar Transistors) have 8 control signals: bit1 clocks the IGBT gate control level according to the selected direction (bit 4); bit 2 . . . 4 turns on or off the comparison of the shunt voltage to a preselected reference voltage 116. Each shunt voltage signal can be routed 105 to either of the 4 IGBTs; bit 5 selects the direction the magnet current ramp is approaching the comparison of the shunt voltage to the reference voltage; bit 6 resets the shunt logic to standby; bit 7 enables the shunt logic control; bit 8 selects the shunt logic control for up or down ramp comparison with a preselected reference voltage. In an embodiment, the shunts 106 are custom built and water cooled (although it should be understood that other methods of cooling, are contemplated and therefore within the scope of the present invention), 107 represents IGBT drivers that are optically isolated from the SDL (security and Driver Logic) electronics. They monitor the IGBT voltage and current and signal the SDL board when any overvoltage (voltage spikes) or over current occur.

The SDL electronics switches the field-cycling electronics immediately into standby mode in the situations where standard parameter(s) have been exceeded. In addition, in the ease of overvoltage or overcurrent the driver protects the IGBTs by modifying the gate current. Gate resistor and capacitors are optimized for maximum gate current rise time. IGBTs 108 are type 400 A/3300V and are mounted on a water cooled aluminum plate. 109 represents 4×18 bit digital to analog converters that have preselected values to compare to the shunt voltages. 110 represents the fifth EEPROM (electronically erasable program) that contains the information when to route the Z-gradient waveform (the 4th and 5th coax cables) 112 to the Z-gradient amplifier 111 or to the current amplifier 114 that drives the magnet main current. Bits 1 . . . 6 control six relays 113 for that purpose. In addition, the fifth EEPROM contains the signal indicating when it is appropriate to activate or deactivate the magnetic field regulation 115.

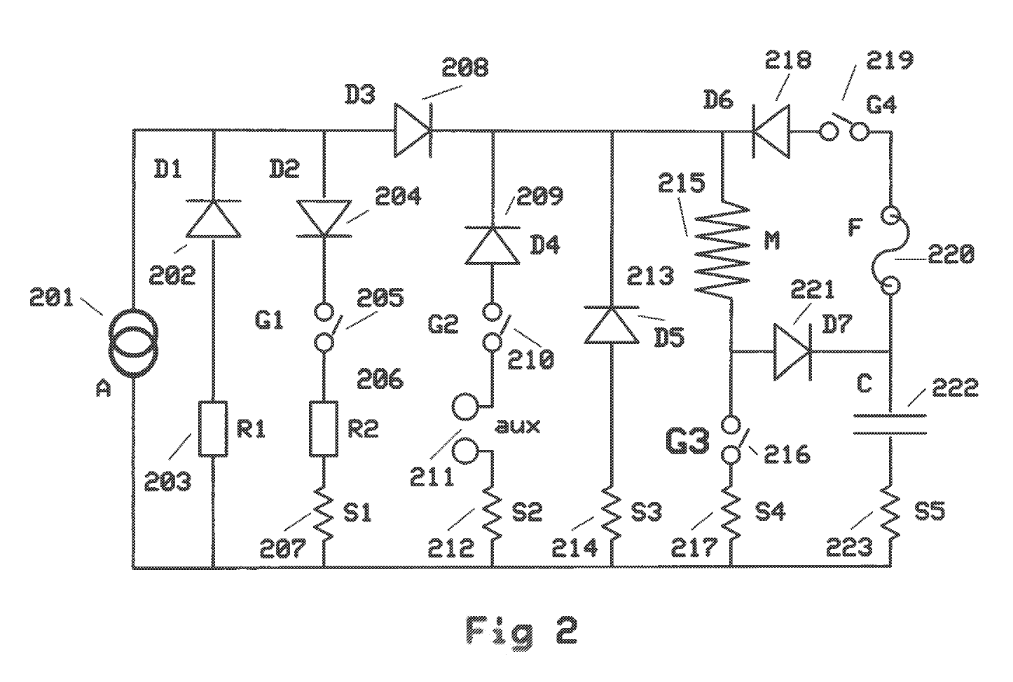

### Principles of Magnetic Field-Cycling (FIG. 2)

FIG. 2 illustrates how the various field cycling components are connected. (A) 201 is the current amplifier that provides the current to the main coil. Diode (D1) 202 and resistor (R1) 203 provide the pass to the current amplifier to generate a negative potential in order to decouple itself from the rest of the circuit. Diode (D2) 204, IGBT (G1) 205, resistor (R2) 206 and shunt (S1) 207 provide a switchable pass for the current amplifier to raise the current to a pre-selected positive level. R2 has the same value as the main coil resistance (in the present case, 0.57 ohm although it should be understood that other resistance levels can be appropriately used depending on the maw coil resistance). Resistors R1 and R2 are 1000 W custom made resistors. Diode (D3) 208's function is to decouple the current amplifier during fast ramp intervals. Diode (D4) 209, IGBT (G2) 210; Input (aux) 211 and shunt (S2) 212 provide an auxiliary input to a second current amplifier or battery supply. Diode (D5) 213 and shunt (S3) 214 are the return pass fur the main coil after reaching the selected level using the high voltage of the storage capacitor (C) 222.

The main coil (M) 215 is a magnet with a bore size of 20 cm ID (inner diameter), a length of 80 cm, an inductance of 0.118 Henry and a resistance of 0.57 ohm. The coil is imbedded in epoxy and is water cooled (although other solvents may be appropriately used). The IGBT (G3) 216 and shunt (S4) 217 are the current pass when the magnet is on a stationary level or being ramped up by the current amplifier (A) 201. Diode (D7) 221 provides the fast discharge link to the storage capacitor. In this mode, energy is transferred from the main coil to the storage capacitor. Diode (D6) 217, IGBT (G4) 219, and fuse (F) 220 provide the current link when charging the main coil utilizing the voltage from the storage capacitor C. In this mode, the main coil current ramp is fast. Capacitor (C) 222 and Shunt (S5) 223 are the location of the storage capacitor. In addition to the conventional fuse there may be two electronic fuses that monitor the current through shunt (S4) 217 and (S5) 223 continuously and if exceeding maximum current will switch the FCC-logic into standby mode within 5 micro seconds. This serves to protect the magnet from overcurrent generated by the storage capacitor (C) 222 in the case of a faulty manipulation or component breakdown.

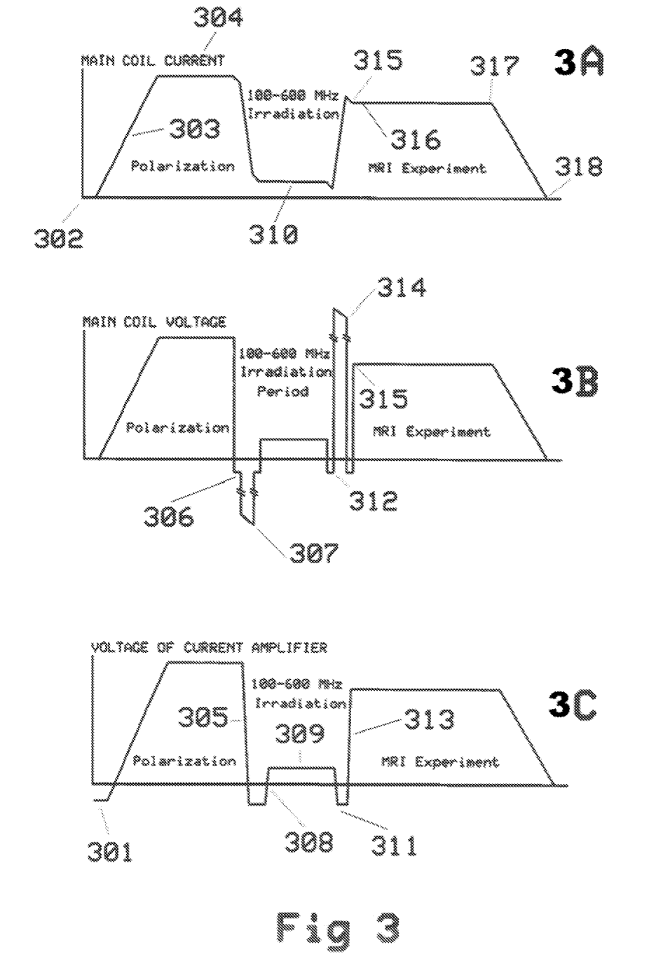

### OMRI Sequence Diagram (FIG. 3)

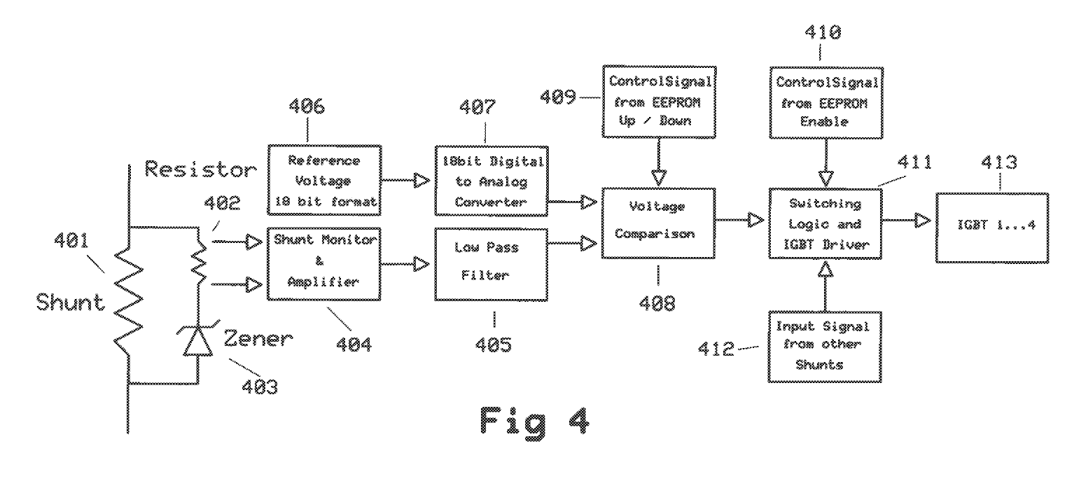

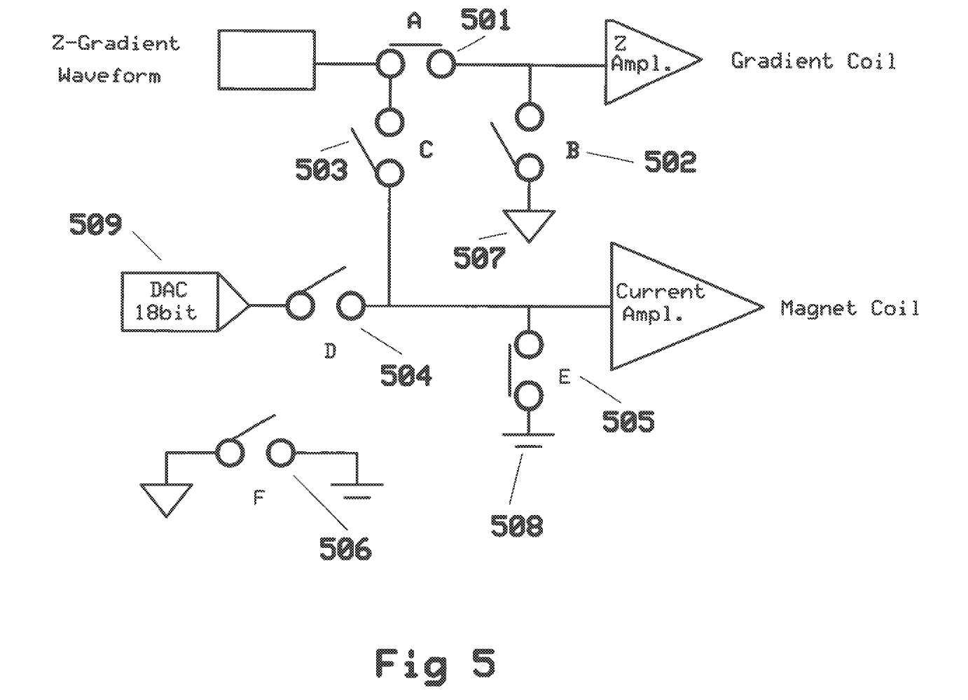

A typical sequence of an Overhauser Enhanced MRI sequence is illustrated in FIG. 4a through FIG. 4e. In the “standby state” at boot-up, all IGBTs (G1 . . . G4) (FIG. 2) are open and any remaining energy in the Main Coil M (FIG. 2) is transferred to the storage capacitor C (FIG. 2). This is also called the “standby state”. In case of malfunction, power interruption, overheating, over current, or overvoltage, the security and interface logic will immediately put the system into standby mode, protecting the Main Coil M (FIG. 2) and other expensive parts. The security and interface logic senses all shunt voltages, temperatures of the Main Coil M (FIG. 2), the storage capacitor, and of the cooling fluid, and drives the IGBTs. The security and interface logic is controlled by the pulse programmer unit of the MRI console. With this approach, all aspects of any field cycling experiment can be controlled at the console. At the beginning of a field cycling sequence 301, the current amplifier has a small negative bias (e.g. about −3 V) generating a small current through diode D1 (see FIG. 2) and resistor R1 (see FIG. 2). At this stage, the relay switches A . . . F (see FIG. 5) are activated to route the Z-gradient driver into the current amplifier. Then, IGBT_3 (G3) 302 (see FIGS. 2 and 3) is switched closed, enabling the current amplifier to ramp up the current in the Main Coil M (FIG. 2) to a high polarization value (e.g. about 0.5 Tesla or 200 amps for the magnet) 303. The ramp slope can be 1 A/msec, depending on the voltage of the current amplifier/Main Coil M (FIG. 2) inductance.

In one embodiment of the present invention, the voltage to inductance may be on the order of about 160 V/0.12 H. After a polarization time of approximately 1 second (shown by 304), IGBT_1 G1 (see FIG. 2) is switched closed and the current amplifier is set to ramp the current down 305. At this instance, the Main Coil M (FIG. 2) resistive voltage is offset by an equal and opposite induced voltage that is limited by the diode D5 (FIG. 2). The Main Coil M (FIG. 2) is now a current source that is discharging at as rate of 100 V/0.12 H or less than 1 A/msec. This enables the current amplifier to ramp down at a much faster rate without increasing voltage. After a period of 100 us, the current amplifier has again reached a negative bias of −3 V and is decoupled from the Main Coil M (see FIG. 2) by diode D3 (FIG. 2). At this time, IGBT_3 G3 (FIG. 2) is switched open 306, which increases the induced voltage over the Main Coil M (FIG. 2) to be equal to the voltage over the storage capacitor C (Fig. 2). The storage capacitor is charged to 2800 V prior to executing the sequence; and now the Main Coil M (FIG. 2) is discharging at a rate of 2800 V/0.12 H at about 23 A/msec. As soon as shunt S3 (see FIG. 2) or shunt S5 (see FIG. 2) have reached a preselected level of 10 A (or some other preselected level), IGBT_3 (G3) (FIG. 2) is switched closed again 307. At this instance, the induced voltage over the coil will be equal to the resistive voltage again. That resistive voltage at 10 A is 5 V, a preselected level. At the same time, the current amplifier will ramp up to meet the current in the Main Coil M (FIG. 2) 308.

The current amplifier will also generate the current through resistor R2 (FIG. 2) (0.5 ohm) and will therefore generate 20 A current. There is no need to switch IGBT_1 G1 (FIG. 2) to open because the currents are relatively low. The next period in the sequence is the irradiation period 310 (or evolution period). During this period, a preselected radiofrequency of anywhere between 100 . . . 600 MHz is irradiated to transfer magnetization from the unpaired electron to the water hydrogen, mediated by the oxygen concentration (when using an appropriate contrast agent, e.g. Oxo63). After a pre-determined period of between about 10 msec to 300 msec 309, the current amplifier will ramp down to −3 V in a period of 50 μs 311 detaching itself again from the Main Coil M (FIG. 2) by diode D3 (FIG. 2). At this time, the IGBT_4 G4 (FIG. 2) switch is closed 312, which will put the Main Coil M (FIG. 2) parallel to the storage capacitor C (FIG. 2). The voltage from the storage capacitor (˜3000 V) is now over the Main Coil M (FIG. 2) in the same direction as the resistive voltage.

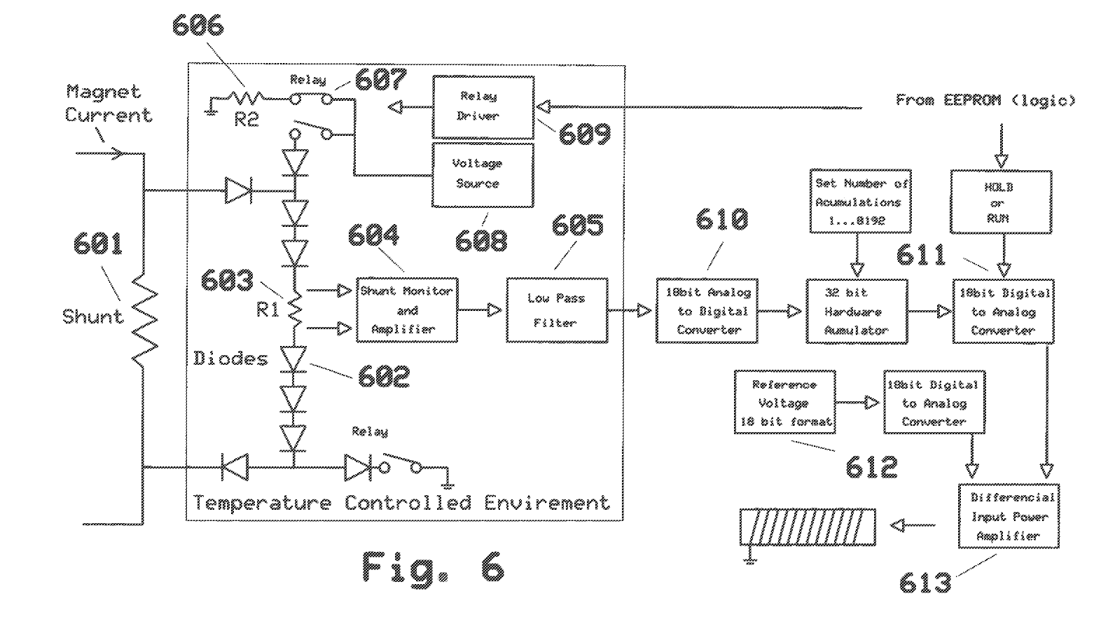

As a result, the current in the coil now increases with an initial rate of 3000 V/0.12 H or 35 A/msec. A 300 A (FIG. 2) fuse F is in series with the Main Coil M (FIG. 2) to protect the Main Coil M (FIG. 2) from accidental over current, in addition to two electronic fuses that monitor shunt (S4) and shunt (S5) for overcurrents. At the same instant, the current amplifier ramps the current through resistor R2 (FIG. 2) up to 200 A within 100 μs 313. When shunt S4 (FIG. 2) detects 200 A, IGBT_4 G4 (FIG. 2) will be switched open again 314, which will remove the storage capacitor C (FIG. 2) from the Main Coil M (FIG. 2) and put the Main Coil M (FIG. 2) into discharge mode of 130 V/0.12 H or ˜1 A/msec. After a 50 μs settling, time, IGBT_1 GI (FIG. 2) is opened again 315. No the Main Coil M (FIG. 2) is powered by the current amplifier providing a current of 200 A for the period of executing the MRI sequence (˜100 ms). At this point, the relay switches A . . . F (FIG. 5) are changed to route the Z-gradient back to its original position (FIG. 5) and the current amplifier is now driven by the 18-bit DAC that has as preselected value that corresponds to 200 A. After an additional 50 μs, the current stabilizer (FIG. 6) is switched from the HOLD to the ON position 316 and will correct and/or change the magnetic field to the original strength determined at calibration time. Using this approach produces an extremely precise and reproducible current for the acquisition period. Accordingly, the MRI experiment(s) can now be executed. At the end of MRI sequence 317, the Current amplifier ramps the current down in an orderly fashion and leaves the system in standby mode again by switching IGBT_2 to open 318. In one embodiment, the IGBT's and diodes are mounted on an aluminum plate that is water cooled.

### Shunt Voltage Detection and IGBT Switching (FIG. 4)

FIG. 4 illustrates how the shunt voltage is detected, amplified, and compared and shows if the voltage reaches a level wherein the instrument will turn on or off the selected IGBTs, according to the program stored in the EEPROM. This is part of the Security and Driver logic (SDL) of the field cycling electronics. The SDL circuit includes all IGBT drivers, the shunt sampling, and the interface to the MRI or NMR console. Each shunt can be programmed to control any of the IGBTs.

FIG. 4 illustrates how an IGBT is controlled. At the beginning of a cycle, the system is in Standby mode, and all IGBTs are switched open. To start a field-cycling experiment, the operator executes a pulse program that includes the field-cycling commands. Field-cycling commands are instructions that turn on and off three real time clocks (RTC) pulse (Reset, Arm, and Advance). A program is selected in the EEPROM that corresponds with the desired pulse program in the MRI or NMR console. The experiment starts by setting the Arm signal to logic 1 (high). The Arm signal will then enable the field-cycling instrument to switch according to the sequence stored in the EEPROM. Shunt 401 is a custom made 1000 Watt resistor of 20 milliohms that is held at constant temperature by controlled water cooling. At 200 A shunt 401 will generate a 4 volt drop. A resistor 402 and a Zeiler diode 403 of 4 V are switched in parallel. The voltage over the resistor is the product of the current through the Zener diode times the resistor (U=R×1). This voltage is offset to zero by the “zero drift” shunt monitor and amplifier. Any deviation from this level (0 Volt level) is amplified by 80 db 404, filtered 405, and compared 408 with a reference voltage 406 that is converted 407 to an analog voltage level. Depending on the control signal from the EEPROM 409, the voltage comparison is either an up-down event or a down-up event. When the shunt voltage has reached the same level as the reference voltage, a signal is passed on to the switching and driver logic. The program in the EEPROM enables the control signal 410 to instruct the input signal from either shunt 412 to switch the IGBT 413.

### Relay Configuration (FIG. 5)

FIG. 5 illustrates how six relays can be configured to switch the Z-gradient to ramp up the magnet. Using the MRI instrument's Z-gradient waveform to ramp up the main coil enables one to have full control over execution of the field-cycling electronics from the MRI console. In the standby mode, the Z-gradient waveform is connected to the gradient amplifier with its ground potential 507 disconnected from the field-cycling electronics ground 508 by having relay (F) 506 open. During the main coil ramp time using the current amplifier, relays A, B, C, E and F are switched from the standby position, enabling the Z-gradient waveform to drive the current amplifier. Once the appropriate current level is reached, the DAC 509 will provide the holding level by closing, relay (D) 504. At this instance, relays A. B, C and F can be switched back to their standby mode. At this point, the current amplifier is driven by the DAC and the MRI instrument ground is disconnected again; and the relay (F) 506 is open again. The entire field-cycling electronics ground is now floating and the negative output of the current amplifier defines the ground potential. This is possible because in one embodiment, the field-cycling electronics is powered by four 12 V marine batteries. Using this approach will minimize electrical noise as well as potential ground loops during the execution of a MRI sequence, which consequently enables the current/field regulation to work to its full potential.

### Magnetic Field Stability (FIG. 6)

For current generation during the polarization and irradiation periods, a computer controlled current amplifier can be used (e.g., Copley Controls amplifier). The irradiation (evolution) period is when the Overhauser-Enhancement occurs by saturating electron transition(s). Current stability generally is not of the utmost importance because the EPR line width is more than 500 kHz. The current stability of a regular current amplifier is sufficient for both periods. During the MRI experiment period a current/field stabilizer that is powered by batteries can be used, which has several advantages. First, a current/field stabilizer that is powered by batteries does not have short term instabilities generated by a power grid. Furthermore, the noise floor is approximately 40 dB lower than that from a regular power supply that derives its power from the power grid. That enables one to detect the changes in the electrical current finely and precisely, allowing one to consequently correct the magnetic field strength. FIG. 6 illustrates one embodiment of a magnetic field regulator. A water-cooled shunt resistor 601 with a pre-selected resistance m the range of 5 to 50 milliohms generates a voltage drop of 5.1 V for a corresponding magnet current in the range of 100 A to 1000 A. Magnet current deviations of less than 1 ppm are detected by a circuit parallel to the shunt, comprising seven low-noise Diodes 602 and a resistor 603. The circuit generates a voltage drop of 4.9 V over the seven diodes and a voltage of 0.2 V over the resistor 603 at the operating current. A 1 ppm deviation of the magnet current will generate a voltage change of 200 nV over the resistor. The resistor voltage is amplified by 80 db by a “zero drift” and less than 1 ppm stable shunt monitor amplifier 604. A 200 nV deviation will generate a 2 mV deviation at the output of the amplifier.

The detection circuit is located in a double wall temperature enclosure that has a temperature controller between the two walls. With this approach, outside temperature change of 15 degrees C. will not affect the less than 1 ppm stability of the shunt monitor amplifier.

In addition, when the magnet current is less than the full value current, an auxiliary current is switched through the seven diodes 602 and resistor 603 to eliminate temperature effects from self-heating or cooling. The relay 607 is turned on and off by the EE-prom during a field-cycling sequence. Furthermore, the resistor 606 is fine tuned to eliminate any additional self-heating or cooling effects from the voltage source 608 or relay driver 609 when switching the auxiliary current. With this approach, the temperature effects from the changing magnet current does not affect the temperature stability of the shunt monitor amplifier.

The detected voltage over the resistor 603 is then offset to zero by the “zero drift” shunt monitor and amplifier.

Any deviation from this level will be amplified by 80 db. The active range is approximately 1%. That is, approximately 1% is 200 KHz for a 20 MHz proton frequency. An 18 bit digitizer module would then give a resolution of <1 Hz. 1 ppm of 20 MHz is 20 Hz. The amplified resistor voltage 604 is filtered 605 and digitized 610 at a 1 s conversion rate, and accumulated and averaged to improve the signal to noise. The number of accumulations can be selected in a range of 1 K to about 8 k to optimize the stability. Part of the main frequency (20 MHz) calibration before executing an MRI sequence is the loading of the holding registers of the two digital to analog converters (DAC). DAC1 611 keeps the initial value while DAC2 612 changes according to the current sensed at the shunt. Amplifier 613 will generate a current that is calibrated to the digital resolution (1 Hz per bit). Diodes protect the amplifier during the field ramping period. The B0 correction coil can be either the B0 compensation coil of the gradient coil or a separate coil.

With this unique new approach, the present invention will be able to stabilize the magnetic field to better than 1 ppm and additionally correct for magnetic field changes generated by temperature changes of the coil wire or power supply.

Thus, in an embodiment, the field cycling instrument of the present invention can be used to detect cancer. For example, in one embodiment, the field cycling MRI can be used to target various receptors, for example, the EGFR/HER2 receptors using various ligands. It is expected that the Overhauser-enhancement approach will be useful in these experiments. In an embodiment, the present invention relates to a magnetic resonance field-cycling instrument comprising one or more of an electronic fast switching insolated gated bipolar transistors or a storage capacitor in order to power field-cycling electronics, which allows a user to perform field cycling experiments in a magnet on a sample size that is greater than about 5 cm and less than about 25 cm in diameter. In a variation, the sample size that is greater than about 5 cm and less than about 20 cm in diameter. In a variation, the sample size that is greater than about 5 cm and less than about 15 cm in diameter. In a variation, the sample size that is greater than about 5 cm and less than about 10 cm in diameter.

In one variation, the magnetic resonance field cycling instrument is able to accommodate a sample that has a length of between about 1 cm and 8 cm.

In one variation, the magnetic resonance field cycling instrument comprises at least one insolated gated bipolar transistor and at least one storage capacitor. In one variation, the field cycling instrument of the present invention is able to take advantage of hyper-polarization.

In an embodiment, the field cycling instrument further comprises one or more of high voltage diodes; one or more current amplifiers; one or more resistors, one or more shunts; and One or more fuses.

In an embodiment, the one or more resistors are selected so as to have an equal value to a resistance of the magnet.

In one variation, the magnetic resonance field cycling instrument comprises one or more marine batteries that are used to power the field-cycling electronics of the field cycling instrument. In one variation, the field-cycling electronics is powered by four 12 V marine batteries.

In one embodiment, the magnetic field is stabilized to better than 1 ppm.

In one embodiment, the magnetic resonance field-cycling instrument comprises an electronic fast switching insolated gated bipolar transistor and a storage capacitor, wherein said magnetic resonance field-cycling instrument has a magnet that is about 20 cm in an inner diameter and an electronic switching time that is less than about 10 msec. In one variation, the electronic switching time is less than about 5 msec.

1. A magnetic resonance field-cycling instrument comprising one or more of an electronic fast switching insolated gated bipolar transistors or a storage capacitor in order to power field-cycling electronics, which allows a user to perform field cycling experiments in a magnet on a sample size that is greater than about 5 cm and less than about 25 cm in diameter.

2. The magnetic resonance field cycling instrument of claim 1, wherein the magnet in the field cycling instrument is able to accommodate a sample that has a length of between about 1 cm and 8 cm.

3. The magnetic resonance field cycling instrument of claim 2, wherein the field-cycling instrument comprises both an insolated gated bipolar transistors and a storage capacitor.

4. The magnetic resonance field cycling instrument of claim 1, wherein the field cycling instrument is able to take advantage of hyper-polarization.

5. The magnetic resonance field cycling instrument of claim 1, wherein the field cycling instrument further comprises one or more of high voltage diodes; one or more current amplifiers; one or more resistors, one or more shunts; and one or more fuses.

6. The magnetic resonance field cycling instrument of claim 5, wherein the one or more resistors are selected so as to have an equal value to a resistance of the magnet.

7. The magnetic resonance field cycling instrument of claim 1, further comprising one or more marine batteries that are used to power the field-cycling electronics of the field cycling instrument.

8. The magnetic resonance field cycling instrument of claim 7, wherein the field-cycling electronics is powered by four 12 V marine batteries.

9. The magnetic resonance field cycling instrument of claim 7, wherein a magnetic field is stabilized to better than 1 ppm.

10. A magnetic resonance field-cycling instrument comprising an electronic fast switching insolated gated bipolar transistor and a storage capacitor, wherein said magnetic resonance field-cycling instrument has a magnet that is about 20 cm in an inner diameter and an electronic switching time that is less than about 10 msec.

11. The magnetic resonance field-cycling instrument of claim 10, wherein the electronic switching time is less than about 5 msec.

12. The magnetic resonance field-cycling instrument of claim 1 wherein the filed cycling experiment is performed on a sample size that is greater than about 5 cm and less than about 15 cm in diameter.

13. The magnetic resonance field cycling instrument of claim 12, wherein the field-cycling instrument comprises both an insulated gated bipolar transistors and a storage capacitor.

14. The magnetic resonance field cycling instrument of claim 13, wherein the field cycling instrument is able to take advantage of hyper-polarization.

15. The magnetic resonance field cycling instrument of claim 14, wherein the field cycling instrument further comprises one or more of high voltage diodes; one or more current amplifiers; one or more resistors, one or more shunts; and one or more fuses.

16. The magnetic resonance field cycling instrument of claim 15, wherein the one or more resistors are selected so as to have an equal value to a resistance of the magnet.

17. The magnetic resonance field cycling instrument of claim 12, further comprising one or more marine batteries that are used to power the field-cycling electronics of the field cycling instrument.

18. The magnetic resonance field cycling instrument of claim 17, wherein the field-cycling electronics is powered by four 12 V marine batteries.

19. A magnetic resonance field-cycling instrument comprising an electronic fast switching insolated gated bipolar transistors and a storage capacitor in order to power field-cycling electronics, further comprising high voltage diodes, one or more current amplifiers, one or more resistors, one or more shunts; and one or more fuses which allows a user to perform field cycling experiments in a magnet on a sample size that is greater than about 5 cm and less than about 25 cm in diameter.

20. The magnetic resonance field-cycling instrument of claim 19, wherein the field cycling instrument is able to take advantage of hyper-polarization.
